(19) United States
(12) Patent Application Publication
(10) Pub. No.: US 2007/0001165 A1
(43) Pub. Date: Jan. 4, 2007

(54) Memory cell comprising one MOS transistor with an isolated body having a prolonged memory effect

(75) Inventors: Rossella Ranica, Grenoble (FR); Alexandre Villaret, Grenoble (FR); Pascale Mazoyer, Domene (FR)

Correspondence Address: STMicroelectronics Inc.;c/o WOLF, GREENFIELD & SACKS, PC, Federal Reserve Plaza, 600 Atlantic Avenue, BOSTON, MA, 02210-2206, US

(73) Assignee: STMicroelectronics Crolles 2 SAS, Crolles (FR)

(21) Appl. No.: 11/479,220

(22) Filed: Jun. 30, 2006

(30) Foreign Application Priority Data
Jun. 30, 2005 (FR) 05/51837

(51) Int. Cl. H01L 31/00

(52) U.S. Cl. 257/19

(57) ABSTRACT

A memory cell with one MOS transistor formed in a floating body region in which the lower surface of the source and drain regions, outside of the source extension and drain extension regions, rests on an insulating layer.

### BACKGROUND OF THE INVENTION

1. Field of the Invention

The present invention generally relates to DRAM-type memory cells with one transistor formed in a floating body or well delimited depthwise by a junction.

2. Discussion of the Related Art

FIG. 1 is a simplified cross-section view of an example of such a memory cell. This cell comprises an N-channel MOS transistor formed in a floating body region 1 laterally delimited by an isolating ring 2 and, depthwise, by an N-type layer 3 formed in a P-type substrate 4. The MOS transistor comprises, on either side of a gate region 6 surrounded with spacers 7 and resting on a gate insulator 8, N-type source and drain regions 9 and 10. Each of the source and drain regions comprises a deeper more heavily doped region outside of the region defined by spacers 7 and a shallower less heavily doped region under spacers 7.

In the absence of a specific action on the cell, floating body 1 is at a given voltage corresponding to the thermal equilibrium. It has been shown that positive or negative charges could be injected into this body, setting the cell to one or the other of two determined states which will be designated as 1 and 0. According to this substrate biasing, the threshold voltage of the transistor modifies and states 1 and 0 can thus be distinguished.

Further, FIG. 1 shows an N-type conductive well 11 joining buried layer 3 to enable biasing thereof. In the drawing, the biasing terminal is called ISO, and buried layer 3 can be called an insulating layer.

FIG. 2 is a table illustrating the voltages to be applied to the cell in various operation modes thereof. Voltages VISO to be applied to buried layer 3, VS to be applied to the source, VD to be applied to the drain, and VG to be applied to the gate, have more specifically been indicated. In the right-hand column, the conduction current of the transistor measured in these various states, designated as IS and expressed in microamperes while all the voltages are expressed in volts, has been indicated. More specifically, states of writing of a 1 (WR1), of writing of a 0 (WR0), of reading (READ), of holding or retaining (HOLD), and of erasing (ERASE) have been distinguished. The values given in this table are given as an example only and correspond to a specific technology. The relative values of the various voltages and their biasings should essentially be considered. The given example corresponds to a technology in which the minimum possible dimension of a pattern is on the order of 0.12 μm, and in which a gate length on the order of 0.30 μm and a depth of STI insulation regions 2 on the order of 0.35 μm, as well as a gate oxide thickness on the order of 6 nm, have been selected.

Thus, the main states of the cell are the following.
Writing of a 1 (WR1). The MOS transistor is set to a relatively high conduction state (currents on the order of 20 μA). This state can be established for a very short time only, for example, on the order of a few nanoseconds. At the end of this state, when all the applied voltages are brought back to zero, except the buried layer voltage which is preferably maintained at a slightly positive value, for example, 0.4 volt, the memory cell is in the state illustrated in FIG. 3A, that is, positive charges have been stored in the floating body. Once the memory cell is at the thermal equilibrium state, the charges tend, as illustrated, to narrow the space charge areas. The transistor then has a low threshold voltage, that is, in a read state in which the transistor is lightly biased to be conductive, a first current (16 μA in the illustrated example) will be observed for a given gate voltage.
Writing of a 0 (WR0). The transistor is off, its gate being set to a negative voltage, and its source (or its drain) is also set to a negative voltage, whereby the positive charges possibly present in the substrate are eliminated and negative charges are injected after the setting to the conductive state of the body-source or body-drain diode. At the end of this state, as illustrated in FIG. 3B, the space charge areas tend to widen, which results in an increase in the transistor threshold voltage. Thus, in read conditions in which the transistor is lightly biased to the conductive state, a current lower than the current at state 1 (3 μA instead of 16 μA in the illustrated example) is obtained for a same 1.2-V gate voltage as that considered in the previous case.
Reading (READ). The MOS transistor is set to a slightly conductive state, the drain for example only being at a voltage on the order of 0.4 V to limit injections capable of deprogramming the transistor. The current flowing through transistor MOS is measured or, preferably, compared with a reference value ranging between the current values corresponding to states 1 and 0.
Holding (HOLD). No voltage is applied to the transistor. The voltage applied to buried layer 3 is preferably maintained slightly positive to better block the junction between the isolated body and the buried layer in the case where the transistor is programmed at state 1.
Erasing (ERASE). The source/body (or drain/body) junction is biased in the conductive state, which enables evacuating positive charges. Buried layer 3 remains slightly positively biased.

Thus, as discussed previously, the memory effect of a cell according to the present invention is characterized by a difference between a current at state 1 and a current at state 0 for a given drain-source biasing and for a given gate voltage.

### SUMMARY OF THE INVENTION

An object of the present invention is to improve the memory effect of a memory cell comprising a MOS transistor with a floating body.

Another object of the present invention is to provide such a memory cell which is less likely to have its state 1 altered while it is in or switches to a hold state.

To achieve these and other objects, the present invention provides a memory cell with a MOS transistor formed in a floating body region in which the lower surface of the source and drain regions, outside of the source extension and drain extension regions, rests on an insulating layer.

According to an embodiment of the present invention, the region of the floating body is isolated on its lower surface by a junction.

According to an embodiment of the present invention, the floating body region is laterally insulated by insulating trenches.

The present invention also aims at an integrated circuit containing a memory cell of the above type.

The present invention also aims at a method for manufacturing a memory cell of the above type, comprising the steps of forming, on an active silicon area delimited by an insulating trench, a single-crystal SiGe layer and a single-crystal silicon layer; etching the periphery of the SiGe layer under the silicon layer by leaving in place the SiGe layer substantially under the gate region of a MOS transistor formed in the silicon layer; and filling the peripheral recess with an insulating layer. The single-crystal SiGe and silicon layers may be doped in situ.

The foregoing and other objects, features, and advantages, of the present invention will be discussed in detail in the following non-limiting description of specific embodiments in connection with the accompanying drawings.

### BRIEF DESCRIPTION OF THE DRAWINGS

FIG. 1 shows a memory cell comprising a transistor with a floating body;

FIG. 2 is a table illustrating examples of voltages applied to the cell of FIG. 1 in different states;

FIG. 3A shows the structure of FIG. 1 in the hold state after writing of a state 1;

FIG. 3B shows the structure of FIG. 1 in the hold state after writing of a state 0;

FIG. 4 is a simplified cross-section view of a memory cell according to an embodiment of the present invention; and

FIGS. 5A to 5E are cross-section views illustrating an example of successive steps of the manufacturing of a memory cell according to the present invention.

### DETAILED DESCRIPTION

As usual in the representation of integrated circuits, the various cross-section views are not drawn to scale.

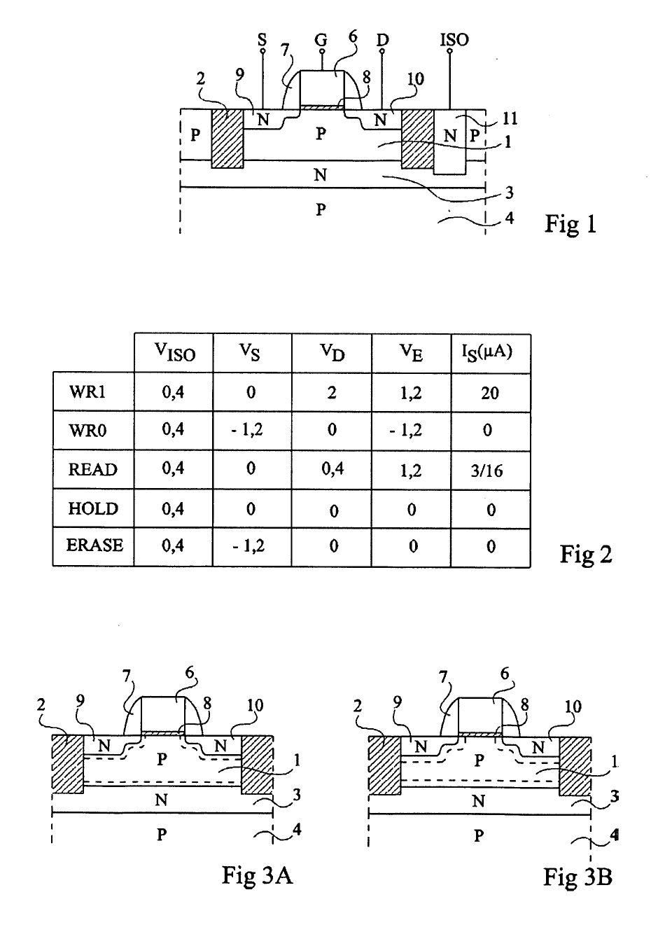

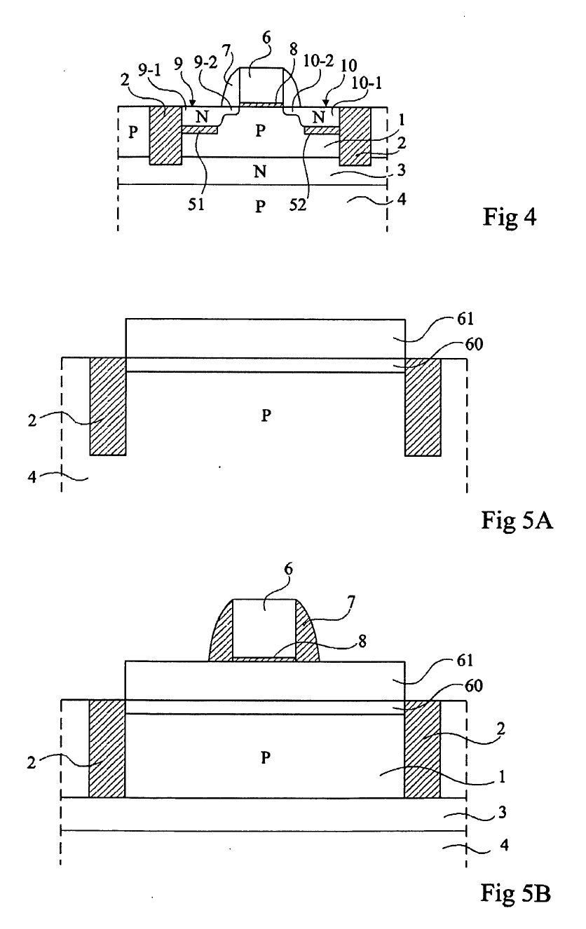

FIG. 4 shows a memory cell according to an embodiment of the present invention shown substantially in the same way as the prior art cell illustrated in FIG. 1. However, conductive region 11 for ensuring the contact with the buried has not been shown in FIG. 4. It can be considered that this region is located in a plane other than the cross-section plane of the drawing or that a single contact transfer region is provided for a memory cell block according to the present invention.

For source 9, the source contact region, generally turned into its upper portion into a silicide to ease the contacts, has been designated with reference numerals 9-1, and more lightly-doped source extension region 9-2, extending substantially under spacer 7, has been designated with reference numerals 9-2. Similarly, for a drain 10, reference numerals 10-1 and 10-2 have been used to designate drain contact region 10-1 and drain extension region 10-2 extending under spacer 7.

According to the present invention, insulating layers 51 and 52 are provided under at least a main portion of the source and drain contact regions, substantially only the source extension and drain extension regions being in contact with floating body region 1.

Providing this insulation of the lower portion of the source and drain regions has several advantages, and especially the following advantages.

Increase in the cell memory effect. All other things being equal, the difference between the read current of a cell programmed to 1 and the read current of a cell programmed to 0 increases. It is considered that this phenomenon is due to the increase in the ratio between, on the one hand, the surface area of the junction of floating body region 1 with buried layer 3 and, on the other hand, the sum of the junction surface areas between source and drain regions 9 and 10 and floating body region 1.

Reduction in leakage during the hold or retention phase and on switching from a phase of programming to 1 to a hold state. Indeed, leakages essentially occur at the level of the junctions between the floating body region and the source and drain regions. Since the junction between the floating body region and the buried layer region is maintained reverse-biased to better block leakages, the leakage surface is in practice limited to the source and drain extension areas.

It should also be noted that the above-mentioned advantages bring about no disadvantages. Especially, at the programming time, essentially the drain and source extension regions cause the injection of carriers into the floating body region and such source and drain extension regions are unaffected according to the present invention.

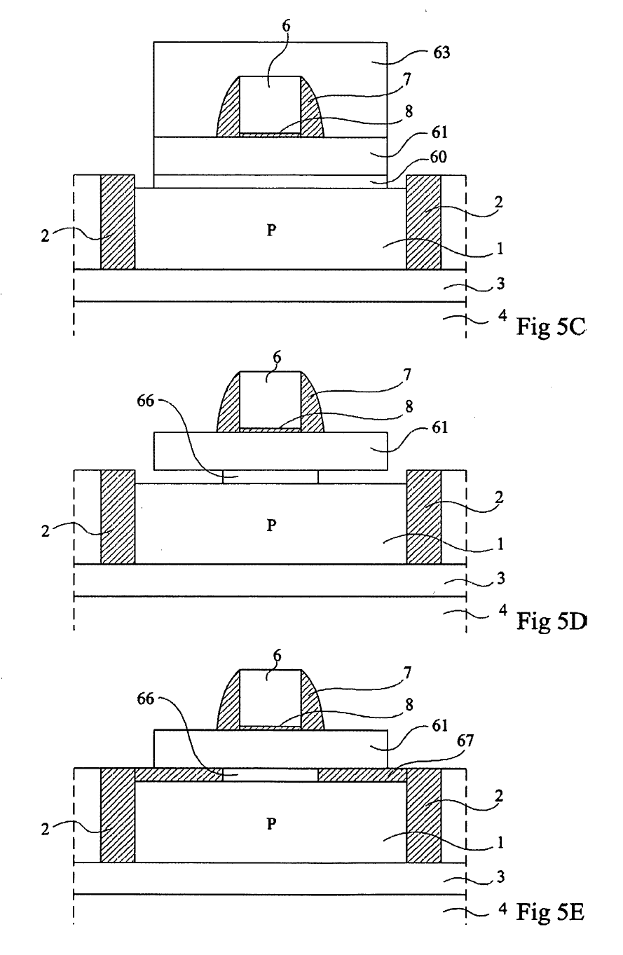

FIGS. 5A to 5E show as an example a possible embodiment of the structure of FIG. 4.

It is started from a P-type substrate 4 in which active regions are delimited by shallow trenches filled with an insulator (STI) 2.

At the step illustrated in FIG. 5A, a layer 60 of a crystal, for example, SiGe, that can grow in single-crystal fashion on single-crystal silicon and on which silicon can grow in single-crystal fashion, is epitaxially deposited. The epitaxial deposition on the SiGe layer of a silicon layer 61 of a thickness corresponding to the thickness which is desired to be obtained for the source and drain contact areas is then performed.

At the step illustrated in FIG. 5B, an N-type implantation is performed in one or several steps, to form buried layer 3 over the entire memory array. A gate pattern comprising a conductive gate 6, currently polysilicon, surrounded with spacers 7 and resting on a thin gate insulator layer 8, is then formed on layer 61.

At the step illustrated in FIG. 5C, a mask 63, for example, a resin mask, is deposited and etched according to a pattern of surface area smaller than that of an active area. By means of this mask, layers 61 and 60 are etched, so that the peripheral edges of layer 60 are disengaged.

At the step illustrated in FIG. 5D, the etching of SiGe layer 60 is continued to leave in place only a small portion 66 substantially above the gate area.

At the step illustrated in FIG. 5E, a filling with an insulator 67, for example, silicon oxide or nitride, of the region located under silicon layer 61 is performed.

A structure corresponding to that shown in FIG. 4 is thus obtained.

It will readily occur to those skilled in the art that the drain extension regions should be formed at the step illustrated in FIG. 5B, before forming of spacers 7, and that the source and drain regions may be formed at one or the other of the manufacturing steps according to the selected technological process. Further, it should be noted by those skilled in the art that it must be ascertained that SiGe and silicon layers 60 and 61 are P-type doped substantially like substrate 4 and more specifically the portion of floating body 1 formed under N implantation region 3. The doping of these various layers 60 and 61 may be performed in various ways known by those skilled in the art, for example, in situ on deposition, or after by implantation-diffusion steps. It should further be noted that this enables optimizing the doping of P layer 61 for an optimal operation of injection by the source and drain regions.

As an example, it may be provided for SiGe layer 60, and thus for insulating layers 67, to have a thickness on the order of 20 nm in the previously-described technology.

The present invention is likely to have various alterations, modifications, and improvements which will occur to those skilled in the art. In particular, the indicated materials and dimensions may be modified according to the technology which is used, provided that the described functions are achieved. Further, although an N-channel MOS transistor has been described, the memory cell may comprise a P-channel MOS transistor, the conductivity types and the polarities of the charges being accordingly modified.

It should be noted that the present invention may also advantageously apply to a DRAM-type memory cell with a transistor formed in a floating body or well delimited depthwise by an insulating layer (SOI).

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A memory cell with one MOS transistor formed in a floating body region, wherein a lower surface of a source region and a drain region, outside of a source extension region and a drain extension regions, rests on an insulating layer;
wherein the region of the floating body is isolated on its lower surface by a junction.

2. The memory cell of claim 1, wherein the floating body region is laterally insulated by insulating trenches.

3. An integrated circuit containing the memory cell of claim 1.

4. A method for manufacturing the memory cell of claim 1, comprising:
forming, on an active silicon area delimited by an insulating trench, a single-crystal SiGe layer and a single-crystal silicon layer;
etching a periphery of the SiGe layer under the silicon layer by leaving in place the SiGe layer substantially under the gate region of a MOS transistor formed in the silicon layer; and
filling the peripheral recess with an insulating layer.

5. The method of claim 4, comprising the in-situ doping of said single-crystal layers of SiGe and silicon.
